(19) United States
(12) Patent Application Publication
(10) Pub. No.: US 2015/0228546 A1
(43) Pub. Date: Aug. 13, 2015

(54) SEMICONDUCTOR DEVICE AND METHOD OF REMOVING SPACERS ON SEMICONDUCTOR DEVICE

(71) Applicant: UNITED MICROELECTRONICS CORP., Hsin-Chu City (TW)

(72) Inventors: Yu-Chun Huang, Tainan City (TW); Shin-Chuan Huang, Tainan City (TW); Tung-Ming Chen, Kaohsiung City (TW)

(73) Assignee: UNITED MICROELECTRONICS CORP., Hsin-Chu City (TW)

(21) Appl. No.: 14/177,233

(22) Filed: Feb. 11, 2014

(51) Int. Cl. H01L 21/8238; H01L 29/78; H01L 21/311; H01L 27/092

(52) U.S. Cl. CPC H01L 21/823864; H01L 27/0928; H01L 29/7833; H01L 21/823892; H01L 21/311

(57) ABSTRACT

A manufacturing method for a semiconductor device includes: providing a substrate including a first gate structure disposed thereon, wherein the first gate structure includes a first gate electrode and a first hard mask covers the first gate electrode. A first oxide spacer and a silicon carbon nitride spacer are formed in sequence to surround the first gate electrode. A thermal treatment is performed to form a silicon oxycarbonitride layer between the first oxide spacer and the silicon carbon nitride spacer. Then, a second oxide spacer, a third oxide spacer, and a first silicon nitride spacer are formed on the silicon carbon nitride spacer in sequence. The first hard mask and the first silicon nitride spacer are removed. Finally, the third oxide spacer, the second oxide spacer, and silicon carbon nitride spacer are removed entirely to expose the silicon oxycarbonitride layer.

### BACKGROUND OF THE INVENTION

1. Field of the Invention

The invention relates to a semiconductor device and a method of removing spacers on the semiconductor device.

2. Description of the Prior Art

Reductions in size and inherent features of semiconductor devices over the past few decades have enabled continued improvements in speed, performance, density, and cost per unit function of integrated circuits. With the continuous scaling down of integrated circuits, conventional methods for improving performance of metal-oxide-semiconductor (MOS) devices, such as shortening gate lengths of MOS devices, have run into bottlenecks.

To enhance the performance of MOS devices, stresses may be introduced in the channel region of a MOS device in order to improve its carrier mobility. A commonly used method for applying compressive stress to the channel regions of PMOS devices is to grow a SiGe epitaxial layer in the source and drain regions, and then applying tensile stress to the channel regions of NMOS devices by growing a SiC epitaxial layer using a selective epitaxial growth method.

The epitaxial layer is formed within two recesses in the substrate besides a gate structure. There is usually a disposable spacer on sidewalls of the gate structure or on a first spacer of the gate structure in order to define positions for forming the recesses. After the epitaxial layer is grown in the recesses, the disposable spacer will be removed.

As the size of semiconductor structures keeps shrinking, semiconductor industries contrive to ensure that the device will not be impacted when forming or removing elements by which the device is constructed. For example, it has been found that the first spacer is always consumed and damaged when removing the disposable spacer, and may even damage the profile of the gate structure.

Therefore, there is still a need for a manufacturing method for a semiconductor device that is able to protect elements of the semiconductor device from being impacted during removal of the disposable spacer

### SUMMARY OF THE INVENTION

According to an aspect of the present invention, a manufacturing method for a semiconductor device is provided. The manufacturing method comprises: providing a substrate comprising a first gate structure disposed thereon, wherein the first gate structure comprises a first gate electrode and a first hard mask covers the first gate electrode. Then, a first oxide spacer is formed to surround the first gate electrode. Next, a silicon carbon nitride spacer is formed to cover the first oxide spacer. Thereafter, a thermal treatment is performed to forma silicon oxycarbonitride layer between the first oxide spacer and the silicon carbon nitride spacer. Next, a second oxide spacer, a third oxide spacer, and a first silicon nitride spacer are formed on the silicon carbon nitride spacer in sequence. Subsequently, the first hard mask and the first silicon nitride spacer are removed. Finally, the third oxide spacer, the second oxide spacer, and silicon carbon nitride spacer are removed entirely to expose the silicon oxycarbonitride layer.

According to another aspect of the present invention, a semiconductor device comprises: a substrate comprising a p-well, a first gate electrode disposed on the p-well, an oxide spacer surrounding the first gate electrode and a silicon oxycarbonitride layer covering the oxide spacer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-9 are drawings illustrating a manufacturing method for a semiconductor device according to a preferred embodiment of the present invention, wherein FIG. 10 shows a plot of thicknesses of spacers versus wafer number.

### DETAILED DESCRIPTION

FIGS. 1-9 are drawings illustrating a manufacturing method for a semiconductor device provided by a preferred embodiment of the present invention. Please refer to FIG. 1. A substrate 10 is provided. The substrate 10 is divided into an NMOS region 12 and a PMOS region 14. An NMOS will be formed within the NMOS region 12 and a PMOS will be formed within the PMOS region 14 . Then, a p-well 16 is formed within the NMOS region 12, and an n-well 18 is formed in the PMOS region 14. Later, a first gate structure 20 is formed within the NMOS region 12, and a second gate structure 30 is formed within the PMOS region 14. The first gate structure 20 includes a first dielectric layer 22 positioned on the substrate 10, a first gate electrode 24 positioned on the first dielectric layer 22, and a first hard mask 26 positioned on the first gate electrode 24. The second gate structure 30 includes a second dielectric layer 32 positioned on the substrate 10, a second gate electrode 34 positioned on the second dielectric layer 32, and a second hard mask 36 positioned on the second gate electrode 34. The first gate electrode 24 and the second gate electrode 34 may be composed of polysilicon, metal or other conductive materials. According to a preferred embodiment of the present invention, the first gate electrode 24 and the second gate electrode 34 are both doped polysilicon. The first hard mask 26 and the second hard mask 36 are preferably composed of silicon nitride. Later, two first oxide spacers 40, 140 are formed to surround the first gate electrode 24 and the second gate electrode 34, respectively. The first oxide spacers 40, 140 may be silicon oxide which can be formed by oxidizing the first gate electrode 24 and the second gate electrode 34 simultaneously. The first oxide spacers 40, 140 contact the first gate electrode 24 and the second gate electrode 34, respectively. Thereafter, a silicon carbon nitride layer 42 is formed to conformally cover the first gate structure 20, the second gate structure 30, the substrate 10 and the first oxide spacers 40, 140. The silicon carbon nitride layer 42 is preferably formed by an atomic layer deposition (ALD) process.

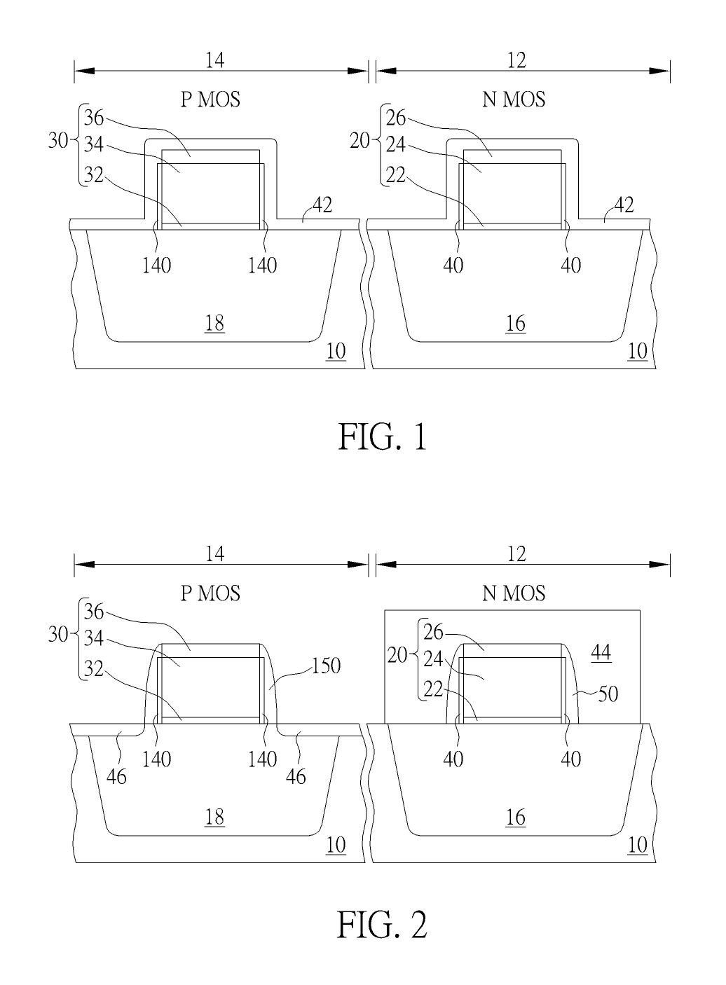

As shown in FIG. 2, the silicon carbon nitride layer 42 is etched to form two silicon carbon nitride spacers 50, 150 surround the first oxide spacer 40 on the first gate structure 20 and the first oxide spacer 30 on the second gate structure 140, respectively. Subsequently, a patterned photoresist layer 44 is formed to cover the first gate structure 20, the first oxide spacers 40, and the silicon carbon nitride spacer 50 within the NMOS region 12. Later, an implantation process is performed to form lightly doped regions 46 in the substrate 10 at two sides of the second gate structure 30 by taking the silicon carbon nitride spacer 150 and the second gate structure 30 as a mask. Next, the pattern photoresist layer 44 is removed.

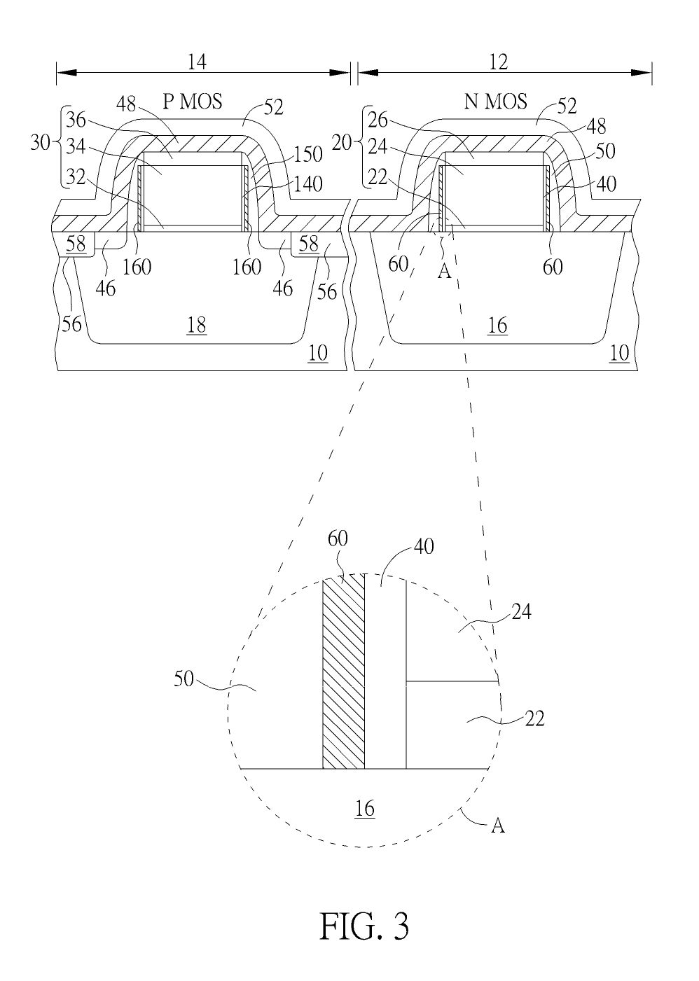

As shown in FIG. 3, a second oxide layer 48 is formed conformally on the first gate structure 20, the second gate structure 30, the silicon carbon nitride spacers 50, 150, and the substrate 10. Additionally, a thickness of the second oxide layer 48 is about 15 Å, and the second oxide layer 48 is preferably formed by an atomic layer deposition (ALD) process. The second oxide layer 48 may be silicon oxide. Then, a silicon nitride layer 52 is formed conformally to cover the second oxide layer 48. The silicon nitride layer 52 may be silicon nitride. Next, a thermal treatment is performed. During the thermal treatment, two silicon oxycarbonitride layers 60, 160 are respectively formed between the first oxide spacer 40 and the silicon carbon nitride spacer 50 on the first gate structure 20, and between the first oxide spacer 140 and the silicon carbon nitride spacer 150 on the second gate structure 30. Furthermore, the lightly doped regions 46 within the PMOS region 14 can also be activated during the thermal treatment. It is noteworthy that, during the thermal treatment, there is no lightly doped region disposed in the NMOS region 12. The lightly doped region within the NMOS region 12 will be formed later.

A circle A marked in FIG. 3 shows a magnified view of the first oxide spacer 40, the silicon carbon nitride spacer 50, and the silicon oxycarbonitride layer 60. As shown in the magnified view, the silicon oxycarbonitride layer 60 is between the first oxide spacer 40, and the silicon carbon nitride spacer 50 on the first gate structure 20 of FIG. 3. For the sake of brevity, only a magnified view of the silicon oxycarbonitride layer 60 on the first gate structure 20 is shown. The silicon oxycarbonitride layer 160 on the second gate structure 30 has the same relative position as the silicon oxycarbonitride layer 60 on the first gate structure 20. It is noteworthy that the silicon oxycarbonitride layers 60, 160 are obtained by reaction between first oxide spacers 40, 140 and the silicon carbon nitride spacers 50, 150 on the first gate structure 20, and the second gate structure 30 during the thermal treatment.

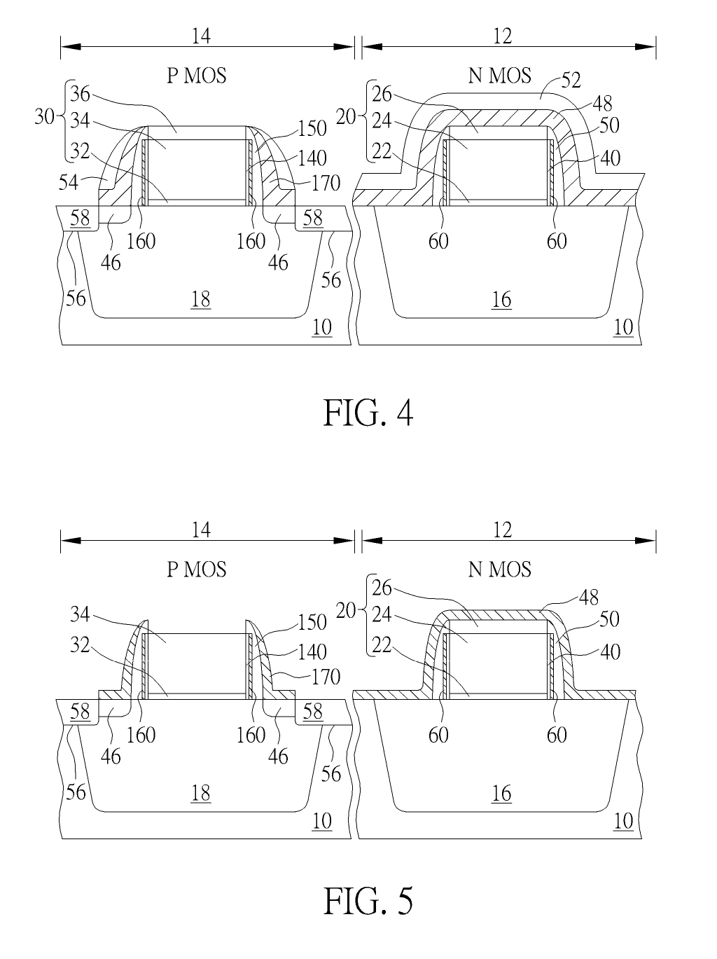

As shown in FIG. 4, the silicon nitride layer 48 and the second oxide layer 52 on the second gate structure 30 are etched to formed a second oxide spacer 170 surrounds the silicon carbon nitride spacer 150, and a silicon nitride spacer 54 surrounds the second oxide spacer 170. The silicon nitride spacer 54 and the second oxide spacer 170 together serve as a disposable spacer. The second hard mask 36, the silicon nitride spacer 54, and the silicon nitride layer 52 serve as an etching mask and an etching process is performed to form a recess 56 in the substrate 10 at two sides, respectively, of the silicon nitride spacer 54 of the second gate structure 30.

After forming the recess 56, a pre-clean process is performed by using diluted hydrofluoric acid or SPM solution containing sulfuric acid, hydrogen peroxide, and deionized water to remove native oxides or other impurities from the surface of the recesses. Subsequently, a selective epitaxial growth (SEG) process is performed on an epitaxial layer 58 such as an epitaxial silicon-germanium (SiGe) layer along the surface of the recess 56. Because a lattice constant of the epitaxial layers is different from that of silicon, this characteristic is employed to cause alteration to the band structure of the silicon in the channel region. Accordingly, carrier mobility of the channel region of the semiconductor device is enhanced and device performance is improved.

As shown in FIG. 5, a removing step is performed to remove the silicon nitride spacer 54 and the second hard mask 36 on the second gate electrode 34, and the silicon nitride layer 52 on the first gate structure 20 in the same step. After the removing step, the second gate electrode 34, the second silicon oxide spacer 170, and the second oxide layer 48 are exposed. Since the second hard mask 36, the silicon nitride spacer 54 and the silicon nitride layer 52 are all silicon nitride, they can be removed by the same etchant. It is noteworthy that the etchant in this removing step can slightly etch the silicon oxide. Therefore, after the removing step, the second oxide spacer 170 on the second gate structure 30 and the second oxide layer 48 on the first gate structure 20 are thinned.

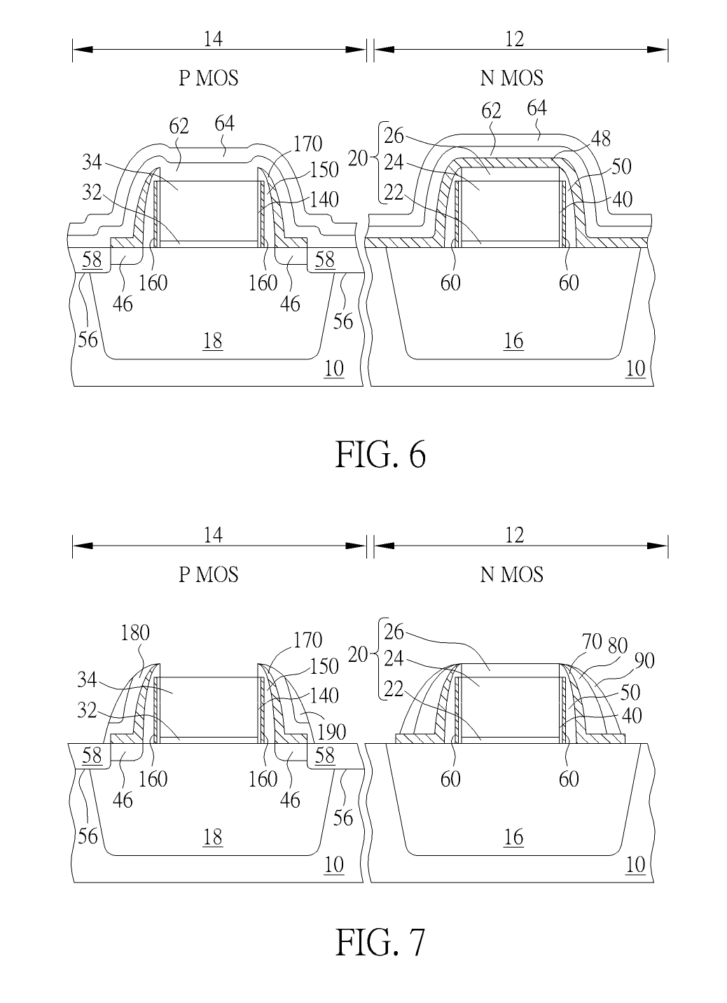

Please refer to FIG. 6. A third oxide layer 62 and a silicon nitride layer 64 are formed on the first gate structure 20 and the second gate electrode 34. More specifically, the third oxide layer 62 and the silicon nitride layer 64 conformally cover the substrate 10, the first gate structure 20 and the second gate electrode 34. The third oxide layer 62 maybe formed by a chemical vapor deposition (CVD) process, and a thickness of the third oxide layer 62 is about 30 Å. The third oxide layer 62 may be silicon oxide . The silicon nitride layer 64 can be silicon nitride formed by HCD and a thickness of the silicon nitride layer is about 220 Å.

As shown in FIG. 7, an etching process is performed. During the etching process, the second oxide layer 48, the third oxide layer 62 and the silicon nitride layer 64 on the first gate structure 20 are etched to form a second oxide spacer 70, a third oxide spacer 80, and a silicon nitride spacer 90 on the first gate structure; meanwhile, the third oxide layer 62 and the silicon nitride layer 64 on the second gate structure 30 are etched to form a third oxide spacer 180, and a silicon nitride spacer 190. At this point, the second electrode 34 is exposed.

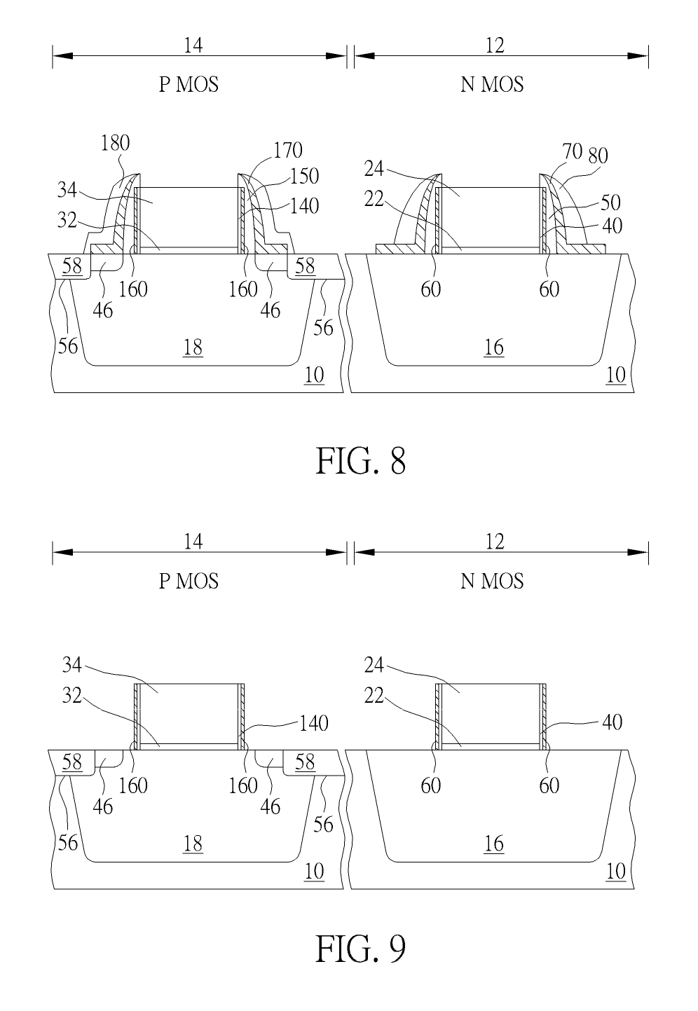

As shown in FIG. 8, the silicon nitride spacers 90, 190 on the first gate structure 20 and on the second gate electrode 34 are removed and the first hard mask 26 is removed at the same step. The third oxide spacers 80, 180, the first gate electrode 24 and the second gate electrode 34 are thereby exposed.

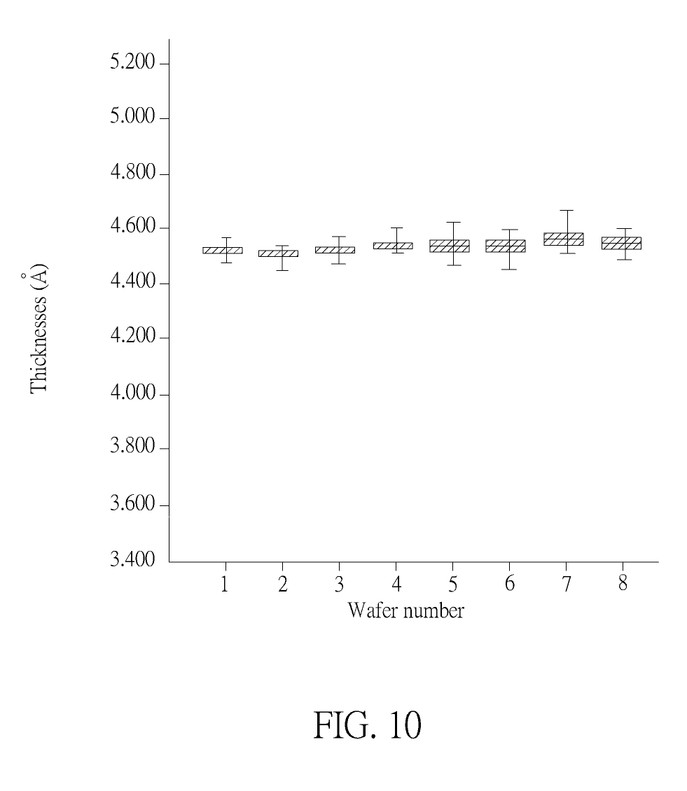

Please refer to FIG. 9. The third oxide spacers 80, 180, the second oxide spacers 70, 170, the silicon carbon nitride spacers 50, 150 on the first gate electrode 24 and the second gate electrode 34 are removed by taking the silicon oxycarbonitride layers 60, 160 on the first gate electrode 24 and the second gate electrode 34 as etching stop layers. The silicon oxycarbonitride layers 60, 160 protect the underneath first oxide spacers 40, 140 from being damaged. Accordingly, the first oxide spacers 60, 160 on the first gate electrode 24 and the second gate electrode 34, respectively, are impervious when removing the third oxide spacers 80, 180, the second oxide spacers 70, 170, and the silicon carbon nitride spacers 50, 150, and thus its profile and width are not consumed. The silicon oxycarbonitride layers 60, 160 on the first gate electrode 24 and the second gate electrode 34 are exposed. Moreover, both a top surface of the first gate electrode 24 and a top surface of the second gate electrode 34 are not covered by any hard mask. Lightly doped regions (not shown) and source/drain regions (not shown) can be formed at two sides of the first gate electrode 24. Since the details of forming lightly doped regions and source/drain regions are well-known to those skilled in the art, details are omitted herein in the interest of brevity.

According to the manufacturing method for the semiconductor device provided by the present invention, the silicon oxycarbonitride layer 60 covers the first oxide spacer 40 which contacts the first gate electrode 24, and the silicon oxycarbonitride layer 160 covers the first oxide spacer 140 which contacts the first gate electrode 34. Thereafter, the silicon oxycarbonitride layers 60, 160 can serve as an etching stop layer when removing other spacers on the gate electrodes 24, 34. Thus the underneath first oxide spacers 40, 140 are protected by the silicon oxycarbonitride layers 60, 160 from being consumed and a thickness of the first oxide spacers 40, 140 can remain uniform. Furthermore, the profile of the gate electrodes 24, 34 can also be protected.

FIG. 10 shows a plot of thickness versus wafer number. Please refer to FIG. 9 again. The thickness of the silicon oxycarbonitride layer 60 and thickness of the first oxide spacer 40 on the first gate electrode 24 within the NMOS region 12 on a wafer are measured. The addition of the thicknesses of the silicon oxycarbonitride layer 60 and the first oxide spacer 40 on the first gate electrode 24 is the y axis of the FIG. 10. There are several wafers undergone the method provided in the present invention. The addition of the thicknesses of the silicon oxycarbonitride layer 60 and the first oxide spacer 40 on each wafer is measured. Each wafer is designated with a wafer number, and the wafer number is the x axis of the FIG. 10. As shown in FIG. 10, the addition of the thicknesses of the silicon oxycarbonitride layer 60 and the first oxide spacer 40 on each wafer is very close. For example, the addition of the thicknesses of the silicon oxycarbonitride layer 60 and the first oxide spacer 40 of each wafer is between 4.4 Å and 4.6 Å. This means that the silicon oxycarbonitride layer 60 successfully serves as an etching stop layer, and the addition of the thicknesses of the silicon oxycarbonitride layer 60 and the first oxide spacer 40 on several wafer are uniform.

Those skilled in the art will readily observe that numerous modifications and alterations of the device and method may be made while retaining the teachings of the invention. Accordingly, the above disclosure should be construed as limited only by the metes and bounds of the appended claims.

1. A manufacturing method for a semiconductor device, comprising
providing a substrate comprising a first gate structure disposed thereon, wherein the first gate structure comprises a first gate electrode and a first hard mask covers the first gate electrode;
forming a first oxide spacer surrounding the first gate electrode;
forming a silicon carbon nitride spacer covering the first oxide spacer;
performing a thermal treatment to form a silicon oxycarbonitride layer between the first oxide spacer and the silicon carbon nitride spacer;
forming a second oxide spacer, a third oxide spacer, and a first silicon nitride spacer on the silicon carbon nitride spacer in sequence;
removing the first hard mask and the first silicon nitride spacer; and
entirely removing the third oxide spacer, the second oxide spacer, and silicon carbon nitride spacer to expose the silicon oxycarbonitride layer.

2. The manufacturing method for a semiconductor device of claim 1, further comprising a second gate structure disposed on the substrate, wherein the second gate structure comprises a second gate electrode and a second hard mask covers the second gate electrode.

3. The manufacturing method for a semiconductor device of claim 2, wherein the first oxide spacer is also formed to surround the second gate electrode.

4. The manufacturing method for a semiconductor device of claim 3, wherein the silicon carbon nitride spacer is also formed to cover the first oxide spacer on the second gate electrode.

5. The manufacturing method for a semiconductor device of claim 4, further comprising forming lightly doped regions in the substrate at two sides of the second gate electrode by taking the silicon carbon nitride spacer as a mask before the thermal treatment is performed.

6. The manufacturing method for a semiconductor device of claim 5, wherein the thermal treatment activates the lightly doped regions.

7. The manufacturing method for a semiconductor device of claim 5, further comprising:
after the lightly doped regions are formed, forming a second oxide layer and a second silicon nitride layer conformally cover the substrate, the first gate structure, the second gate structure, the silicon carbon nitride spacer.

8. The manufacturing method for a semiconductor device of claim 7, wherein the second oxide spacer is also formed on the silicon carbon nitride spacer on the second gate structure.

9. The manufacturing method for a semiconductor device of claim 8, further comprising etching the second oxide layer and the second silicon nitride layer on the second gate structure to form the second oxide spacer, and a second silicon nitride spacer.

10. The manufacturing method for a semiconductor device of claim 9, further comprising:
forming two recesses at two sides of the second gate structure by taking the second silicon nitride spacer as a mask; and
forming an epitaxial layer in the recesses.

11. The manufacturing method for a semiconductor device of claim 10, further comprising:
after the epitaxial layer is formed, removing the second silicon nitride spacer and the second hard mask on the second gate structure and removing the second silicon nitride layer on the first gate structure.

12. The manufacturing method for a semiconductor device of claim 11, wherein when removing the second silicon nitride spacer, the second oxide spacer on the second gate electrode and the second oxide layer on the first gate structure is thinned.

13. The manufacturing method for a semiconductor device of claim 11, wherein the first silicon nitride spacer and the third oxide spacer are also formed on the silicon carbon nitride spacer on the second gate structure.

14. The manufacturing method for a semiconductor device of claim 13, further comprising:
forming a third oxide layer, and a first silicon nitride layer conformally covering the substrate, the second gate electrode, the first gate structure, the second oxide spacer on the second gate electrode and the second oxide layer on the first gate structure; and
etching the first silicon nitride layer, the third oxide layer, and the second oxide layer to form the third oxide spacer, the second oxide spacer and the first silicon nitride spacer on the first gate structure and form the third oxide spacer and the first silicon nitride spacer on the second gate electrode.

15. The manufacturing method for a semiconductor device of claim 14, further comprising:
removing the first silicon nitride spacer on the second gate electrode when removing the first hard mask and the first silicon nitride spacer on the first gate structure; and
removing the third oxide spacer, the second oxide spacer, and silicon carbon nitride spacer on the second gate electrode when removing the third oxide spacer, the second oxide spacer, and silicon carbon nitride spacer on the first gate electrode.

16. A semiconductor device comprising:
a substrate comprising a p-well;
a first gate electrode disposed on the p-well;
an oxide spacer surrounding the first gate electrode; and
a silicon oxycarbonitride layer covering the oxide spacer.

17. The semiconductor device of claim 16, further comprising
an N-well disposed within the substrate;
a second gate electrode disposed on the N-well;
the oxide spacer surrounding the second gate electrode; and
the silicon oxycarbonitride layer covering the oxide spacer.

18. The semiconductor device of claim 17, further comprising:
lightly doped regions disposed within the substrate at two sides of the second gate electrode;
an epitaxial layer embedded in the substrate at two sides of the second gate electrode.

19. The semiconductor device of claim 16, wherein the silicon oxycarbonitride layer is exposed.
